(19) United States
(12) Patent Application Publication
(10) Pub. No.: US 2026/0304600 A1
(43) Pub. Date: Oct. 1, 2026

(54) MEMORY DEVICE WITH EMI SHIELD

(71) Applicant: Micron Technology, Inc., Boise, ID (US)

(72) Inventors: Kyle J. Wilkins, Meridian, ID (US); Prasad Alluri, El Dorado Hills, CA (US); Cory M. Steinmetz, Boise, ID (US); Rahul Mitchell Jairaj, Boise, ID (US)

(21) Appl. No.: 19/097,384

(22) Filed: Apr. 1, 2025

(51) Int. Cl. H05K 1/02; H05K 1/181; H05K 3/22; H05K 3/303; G01R 29/08

(52) U.S. Cl. CPC H05K 1/023; H05K 1/0209; H05K 1/181; H05K 3/22; H05K 3/303; G01R 29/0814; H05K 2201/064; H05K 2201/10151; H05K 2201/10159; H05K 2203/0338; H05K 2203/1322

(57) ABSTRACT

This disclosure is directed to a system for reducing electromagnetic emissions in a memory sub-system. The system comprising a first set of physical components comprising a set of memory devices of a memory sub-system, the first set of physical components having a first set of exposed surfaces. The system comprising a processing device, implemented by a second physical component, coupled to the set of memory devices, the second physical component having a second exposed surface. The system comprising a set of external layers comprising an electromagnetic interference (EMI) shield placed on the first set of exposed surfaces of the first set of physical components and the second exposed surface of the second physical component, the EMI shield configured to reduce electromagnetic emissions from the processing device and the set of memory devices.

### TECHNICAL FIELD

Examples of the disclosure relate generally to electromagnetic interference (EMI) shielding in memory sub-systems and, more particularly, to EMI shield structures and configurations for reducing electromagnetic emissions.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 illustrates a printed circuit board (PCB) on which a memory sub-system including a plurality of layers is implemented, in accordance with some examples.

FIG. 2 illustrates a cross-sectional view of the PCB of FIG. 1, in accordance with some examples.

FIG. 3 is a block diagram illustrating an example computing system that includes the memory sub-system of FIG. 1 with the plurality of layers, in accordance with some examples.

FIG. 4 illustrates a diagram of operations performed for reducing electromagnetic emissions in a memory sub-system, in accordance with some examples.

FIG. 5 illustrates a diagram of operations performed for reducing electromagnetic emissions in a memory sub-system, in accordance with some examples.

FIG. 6 is a block diagram of an example computer system, according to some examples.

### DETAILED DESCRIPTION

The present disclosure relates to electromagnetic interference (EMI) shielding in memory sub-systems. Specifically, the disclosed examples are directed to a system that reduces electromagnetic emissions from at least memory devices and a controller of the memory sub-system through the use of a plurality of layers including an EMI shield that covers at least these memory devices and controller. The EMI shield can include layers that attenuate and contain electromagnetic radiation generated during memory sub-system operations. This shielding approach enhances overall system reliability and performance by inhibiting (ideally preventing) EMI between components of the memory sub-system and components external to the memory sub-system (e.g., host components) while allowing normal memory operations to proceed. The disclosed EMI shielding configuration provides an effective solution for managing electromagnetic emissions in memory sub-systems without impacting thermal management or operational capabilities. This allows the memory sub-system to operate at higher speeds without or with minimal negative impact to other external devices, such as communication systems.

As memory sub-systems achieve increasingly higher operating speeds, they face growing challenges related to EMI that can degrade system performance and reliability. Of particular concern is the harmonic frequency interference between memory devices operating at high transfer rates and common wireless communication frequencies. For example, when a NAND memory device operates at 2400 mega-transfers per second (MT) in open NAND flash interfaces (ONFI)) rates (2400 MT/s ONFI), it can generate electromagnetic emissions at a harmonic frequency that interferes with 2.4 GHz WiFi signals commonly used in consumer and enterprise devices. While EMI shielding has historically been a requirement for memory sub-systems, the rapid advancement of memory speeds and increasing prevalence of wireless technologies necessitates enhanced EMI protection methods. Traditional approaches to EMI management often rely on basic metal enclosures or rudimentary shielding techniques that fail to adequately contain electromagnetic emissions from increasingly dense and high-speed memory devices and processing components.

Inadequate EMI shielding can lead to electromagnetic emissions that interfere with nearby components and other system operations, requiring additional circuit isolation and board space that could otherwise be used more efficiently. For example, lack of adequate EMI shielding in a memory sub-system can cause EMI emissions of the memory sub-system to interfere with external components, such as host system components. This interference can trigger unnecessary error correction cycles and system recoveries that waste processing resources and power. In addition, conventional shielding approaches often employ oversized or improperly configured shields that add unnecessary bulk and weight to memory sub-systems. This excess material not only increases production costs but also creates thermal management challenges by restricting airflow and heat dissipation. Finally, conventional EMI solutions typically use fixed shielding configurations that cannot adapt to varying emission patterns during different memory operations. This inflexibility means shields must be designed for worst-case scenarios, leading to over-engineering and material waste in many usage conditions.

The lack of targeted EMI protection in traditional designs can necessitate additional compensatory measures throughout the system, such as extra ground planes, longer signal routes, or redundant shielding layers. These workarounds increase system complexity and manufacturing costs while potentially reducing overall performance. Conventional approaches often fail to consider the relationship between EMI shielding and other critical system parameters such as thermal management and signal integrity. This oversight can result in conflicting design requirements and suboptimal solutions that compromise system efficiency and reliability.

The present disclosure addresses these inefficiencies by providing a targeted EMI shielding solution that places an EMI shield directly on exposed surfaces to cover physical components implementing the memory devices, controllers and/or processing components of the memory sub-system. Specifically, the EMI shield can be placed to cover a non-conductive layer disposed between the EMI shield and at least the memory devices, controllers, and/or processing elements. This strategic placement and configuration of the EMI shield effectively contains electromagnetic emissions at their source while minimizing material usage and system bulk. The disclosed approach eliminates or reduces the need for redundant shielding layers and compensatory design measures by providing precise electromagnetic containment where it is needed. Additionally, the EMI shield's placement allows for proper thermal management while maintaining effective electromagnetic shielding. This targeted shielding approach reduces system complexity, improves reliability, and achieves more efficient resource utilization compared to conventional solutions.

In some examples, a memory sub-system includes a set of memory devices operatively coupled to a controller, with an EMI shield that covers at least the memory devices and the controller to reduce electromagnetic emissions. The EMI shield can include or be part of a plurality of layers (also referred to as external layers) configured to contain and attenuate electromagnetic radiation generated during system operation and/or manage heat dissipation via a non-conductive layer, such as a thermally conductive material (TCM).

The memory sub-system can be implemented on a PCB having an exposed surface. The physical components implementing the controller and memory devices can be physical chips with specified heights relative to the PCB's exposed surface or layer. In some cases, the EMI shield's height is carefully controlled to be less than or equal to these specified chip heights for optimal shielding effectiveness. In certain implementations, the plurality of layers also include a non-conductive material, such as the TCM that covers and surrounds at least the memory devices and controller. The non-conductive material can include a gel, plastic and/or materials like thermal epoxy or phase change materials, configured to dissipate heat from the memory sub-system components. In some examples, the PCB includes an M.2 interface for host communication, with the non-conductive material deposited directly on the PCB. The TCM may cover or encapsulate passive or active components on the PCB (e.g., voltage regulators), while the EMI shield covers the TCM or non-conductive material-covered areas.

The system can include active EMI management capabilities in some implementations. For instance, the controller may measure electromagnetic emissions using electromagnetic field sensors, compare measurements to threshold values, and adjust operating parameters accordingly. The EMI shield itself may include a metallic layer made up of various materials including metal foils, conductive polymers, metallized fabrics, or specialized alloy coatings to provide effective shielding across operating frequencies. In some examples, the EMI shield incorporates multiple layers with different shielding properties and may include ventilation openings for airflow while maintaining shielding effectiveness. The EMI shield can be integrated with the thermal management system and configured to provide electromagnetic shielding specifically tuned to the memory sub-system's operating frequencies.

The implementation of such systems can follow specific manufacturing methods. In some cases, this involves placing the controller and memory devices on designated PCB portions, depositing a TCM (or non-conductive) layer to cover and/or surround these components, and then placing the EMI shield layer to cover the TCM (or non-conductive) layer. This layered approach ensures both thermal management and electromagnetic shielding are effectively addressed in the final assembly.

Though various examples are described herein as being implemented with respect to a memory sub-system (e.g., a controller of the memory sub-system), some or all of the portions of an example can be implemented with respect to a host system, such as a software application or an operating system of the host system.

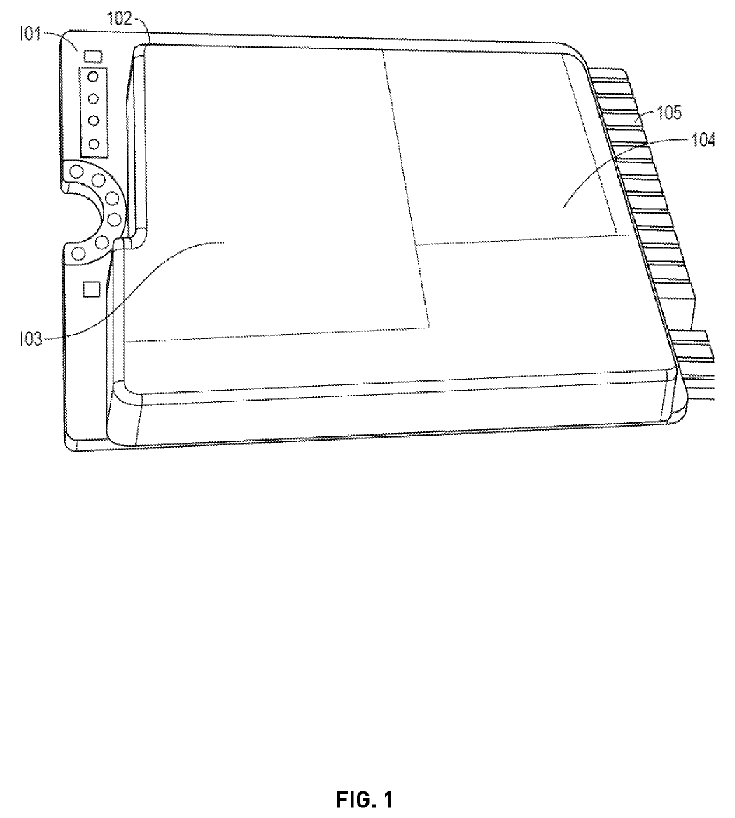

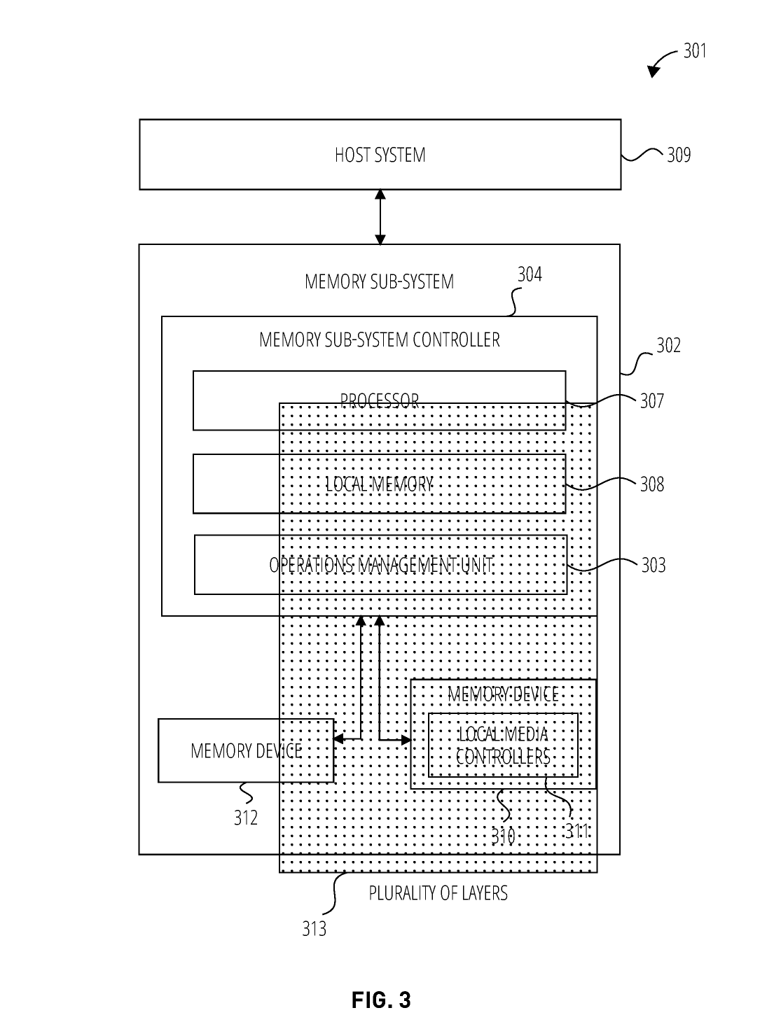

FIG. 1 illustrates a PCB on which a memory sub-system including a plurality of layers is implemented, in accordance with some examples. Specifically, FIG. 1 shows an example physical assembly or PCB 101 having an exposed surface on which a memory sub-system 302 is placed or implemented. An example memory sub-system 302 is shown and described below in connection with FIG. 3. A plurality of layers can cover the exposed surfaces of the physical components implemented on the PCB 101 and this plurality of plurality of layers can include a non-conductive material, such as a TCM (including first portion of the TCM 103 and second portion of the TCM 104), and an EMI shield 102. The non-conductive material can be disposed between the EMI shield 102 and certain components implemented on the EMI shield 102 covered by the non-conductive material. The PCB 101 can implement a solid-state drive (SSD) in some cases. In such cases, the memory sub-system 302 can include the SSD. While the disclosed techniques are discussed with respect to a TCM implementation of the non-conductive material, any other material can be used, such as a gel or plastic.

The PCB 101 includes an interface 105 (e.g., an M.2 interface), the first portion of the TCM 103 that covers a control component, and the second portion of the TCM 104 that covers a memory device component. The EMI shield 102 can be placed on an exposed surface of the first portion of the TCM 103 and second portion of the TCM 104 to cover the first portion of the TCM 103 and the second portion of the TCM 104 and the components (e.g., passive components, active components, a memory controller, and/or memory devices) covered by the first portion of the TCM 103 and second portion of the TCM 104. The M.2 interface can have certain physical dimension restrictions, such as a height that is no greater than 2.3 millimeters, a width no greater than 22 millimeters, and a length no greater than 30 millimeters. In some cases, the M.2 interface can have certain physical dimension restrictions, such as a height that is no greater than 2.3 millimeters, a width no greater than 42 millimeters, and a length no greater than 80 millimeters. Any other suitable physical dimension can similarly be provided.

The control component can include a physical chip or integrated circuit package in which any one of the components of the memory sub-system 302 can be implemented, such as the memory sub-system controller 304, discussed below in connection with FIG. 3. The memory device component can include one or more physical chips or integrated circuit packages in which any one of the memory devices 310 is implemented. The memory sub-system 302 communicates with a host system 309 via the interface 105. In some cases, this communication can produce electromagnetic emissions at a harmonic frequency that can interfere with 2.4 GHz WiFi signals. Also, other components of the memory sub-system 302 can operate at 2400 MT/s ONFI, which can generate electromagnetic emissions at the harmonic frequency that interferes with 2.4 GHz WiFi or other system components. These other components can include passive and/or active components, such as interface connectors or DC-DC converters that emit EMI.

In some cases, the memory sub-system 302 can monitor the current electromagnetic emissions of any of the components implemented on the PCB 101 and adjust the operations of the memory sub-system 302 accordingly, such as by reducing a data rate. The memory sub-system 302 communicates with the host system 309 at a first throughput or data rate. When the memory sub-system 302, such as using the operations management unit 303, determines that a temperature of the control component and/or the memory component reaches or transgresses a temperature threshold or reference temperature, the operations management unit 303 can throttle or reduce the data rate so that the memory sub-system 302 communicates with the host system 309 at a second throughput or data transfer rate. This allows the operations management unit 303 to reduce the operating temperature of the memory sub-system 302 to continue operating without having to shut down any component.

In order to increase the amount of time it takes the memory sub-system 302 to reach the temperature threshold or reference temperature from an ambient temperature, the PCB 101 includes a non-conductive material as one of the plurality of layers that cover components of the memory sub-system 302 on the PCB 101. For example, the non-conductive material can include the TCM physically covering any one or more of the control component, memory component, memory device, passive/active component(s), and/or the interface through the first portion of the TCM 103 and/or the second portion of the TCM 104. The TCM can be a thermally conductive material that is also an electrical insulator.

In some examples, the interface of the PCB 101 is associated with a height restriction. The height restriction limits the total height (e.g., vertical distance between a surface of the PCB and a top portion of any component placed on the PCB). In such cases, the distance or vertical displacement between the surface of the PCB 101 and the top portion of each component on the PCB 101 (including the plurality of layers 313 that is deposited on the PCB including the TCM and/or the EMI shield 102) is set to not exceed the total height of the height restriction, such as 2.3 millimeters. The TCM can be distributed throughout the PCB 101 to cover various empty portions, such as between the control component and the memory devices.

In some examples, the component(s) on the PCB 101 can include physical components that have a height that is smaller than a height of the control component and/or the memory component. In such cases, the TCM is deposited to cover these component(s) to completely encapsulate the component(s).

The EMI shield 102 can be implemented as an additional layer of the plurality of layers placed strategically to cover various portions on the PCB 101 to provide electromagnetic shielding for the components of the memory sub-system 302. The EMI shield 102 works in conjunction with the TCM portions (first portion of the TCM 103 and second portion of the TCM 104) to provide both thermal management and electromagnetic emission reduction. Together the EMI shield 102, the first portion of the TCM 103, and the second portion of the TCM 104 can make up the set of plurality of layers 313, discussed in connection with FIG. 3.

The EMI shield 102 can be placed on the PCB 101 through evaporation-based metallic coating, which can use various metals including aluminum, copper, or tungsten. The EMI shield 102 can be placed on the PCB 101 through electroless-based process deposition and/or through electro-based process deposition. The EMI shield 102 can be placed on the PCB 101 through a solid metallic layer placed around the SSD components, covering the top and optionally all 4 sides for enhanced protection. The EMI shield 102 can be sprayed on certain portions of the PCB 101 covered by the non-conductive layer, such as the TCM. The EMI shield may need to be placed to cover the non-conductive material (and may not be placed on any portion not covered by the non-conductive material) to prevent shorting of components. The TCM can be thermally conductive and electrically insulating.

In some implementations, the EMI shield 102 is configured to conform to the same height restrictions as other components on the PCB 101. Specifically, when the interface has an associated height restriction that limits the total vertical distance between the PCB surface and component exposed surfaces, the EMI shield can be designed to stay within these height constraints while still providing effective shielding.

The EMI shield 102 can be selectively placed over different areas of the PCB 101 based on electromagnetic emission patterns. For example, the EMI shield 102 can be positioned to cover the exposed surface of a physical component including the controller covered by the first portion of the TCM 103 and a set of exposed surfaces of a set of physical components including the memory device covered by the second portion of the TCM 104, as these active components may generate higher electromagnetic emissions during operation, along with other active and/or passive components.

The operations management unit 303 can actively monitor electromagnetic emissions from components on the PCB 101 and adjust operations accordingly. Similar to how the system manages thermal conditions, when electromagnetic emissions exceed certain thresholds, the memory sub-system 302 can reduce data transfer rates or adjust other operating parameters to maintain emissions within acceptable levels.

The EMI shield 102 can include strategic ventilation openings while maintaining effective shielding capabilities. These openings can be configured to allow proper airflow through the TCM portions (first portion of the TCM 103 and second portion of the TCM 104) for thermal management without compromising the shield's ability to contain electromagnetic emissions. This enables the operations management unit 303 to balance both thermal and EMI management requirements while operating within the physical constraints of the PCB 101.

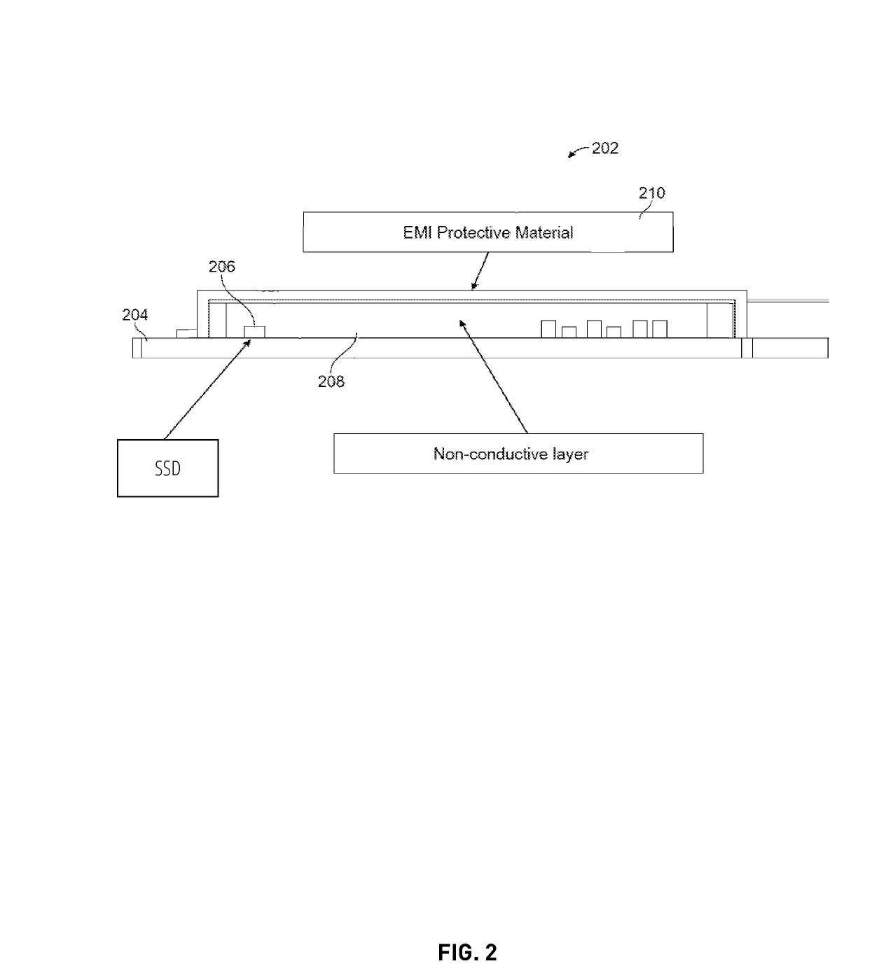

FIG. 2 illustrates a cross-sectional view 202 of the PCB 101 of FIG. 1, in accordance with some examples. Specifically, FIG. 2 shows the cross-sectional view 202 or perspective of the memory sub-system 302 (discussed in connection with FIG. 3) assembly showing the layered configuration of components and protective materials (discussed above).

The cross-sectional view 202 shows a PCB 204 that serves as the foundation, with memory devices and a controller mounted directly on the board. These components are implemented as physical chips having specified heights relative to the PCB surface, which conform to defined height restrictions for the overall assembly. A plurality of layers can be placed to cover various portions of the PCB 204 and can include non-conductive material or layer disposed between an EMI shield 210 and portions of the PCB 204 covered by the non-conductive material or layer, such as TCM 208.

The non-conductive material or layer can include a TCM 208 (or other non-conductive material) deposited on the PCB 204 to cover and/or surround the physical components implementing the memory device, controller and/or processing components (e.g., memory sub-system 206, such as the SSD). The TCM 208 can be made of different materials like thermal epoxy (with conductivity of 1.48 W/mK), urethanes (2.5 W/mK or 0.2 W/mK), silicone adhesives, or phase change materials (0.7 W/m-K thermal conductivity). For smaller components, the TCM 208 provides complete encapsulation, while for taller components it surrounds their sides while leaving surfaces (e.g., top surfaces) exposed.

The EMI shield 210 can be strategically placed to cover exposed surfaces of the TCM or non-conductive material-covered areas. The EMI shield 210 can be constructed from various materials including metal foil layers, conductive polymers, metallized fabrics, carbon-based composites, nickel-copper alloy coatings, silver-based conductive coatings, copper mesh, or zinc-based electromagnetic shielding materials. The EMI shield 210 can incorporate multiple layers with different electromagnetic shielding properties, specifically tuned to the operating frequencies of the memory sub-system 302. These materials are selected and configured to provide optimal shielding effectiveness across various frequencies while maintaining compatibility with the thermal management system.

The height of both the TCM 208 and EMI shield 210 is controlled to remain within specified maximum height restrictions, such as 1.5 millimeters or less from the PCB surface. This ensures compatibility with standard form factors while maintaining effective shielding and thermal management. The EMI shield 210 can include strategically placed ventilation openings that allow proper airflow for thermal management without compromising EMI protection. These openings are positioned to enhance heat dissipation through the TCM layer while maintaining electromagnetic containment.

The operations management unit 303 (shown in FIG. 3) can actively monitor electromagnetic emissions using electromagnetic field sensors positioned around the assembly. When emissions exceed defined thresholds, the operations management unit 303 can dynamically adjust operating parameters like data transfer rates or operating frequencies to maintain emissions within acceptable levels. The memory sub-system 302 can employ multiple approaches for measuring and managing electromagnetic emissions through its operations management unit 303. The operations management unit 303 utilizes electromagnetic field sensors strategically positioned around the assembly to detect and measure field strength near different components like memory devices 310 and processing components, such as memory sub-system controller 304. This allows for real-time monitoring of emission levels in sensitive areas.

Spectrum analysis capabilities enable the operations management unit 303 to measure specific frequency components of electromagnetic emissions. This detailed frequency analysis helps identify particular ranges that may require targeted parameter adjustments or additional shielding measures. When electromagnetic emissions exceed defined thresholds, the operations management unit 303 unit can implement several adjustment strategies. The operations management unit 303 can dynamically reduce data transfer rates between the host system 309 and memory devices 310 while maintaining essential functionality. Additionally, the memory sub-system controller 304 can modify its operating frequencies or those of the memory devices 310 to reduce emissions in specific frequency ranges.

The operations management unit 303 can selectively adjust parameters for specific components generating higher emissions rather than impacting the entire memory sub-system 302. This targeted approach includes adaptive power management, where the operations management unit 303 modifies power delivery and consumption patterns to help reduce electromagnetic emissions while maintaining necessary performance levels. Through continuous monitoring via electromagnetic sensors, the operations management unit 303 makes real-time adjustments to maintain electromagnetic compatibility. This adaptive approach optimizes performance while keeping emissions within acceptable ranges. The operations management unit 303 particularly focuses on frequency ranges corresponding to the memory sub-system's operating frequencies, enabling more targeted and effective emission management.

These measurement and adjustment capabilities work in conjunction with the physical EMI shield 210, which can be constructed from various materials including metal foil layers, conductive polymers, metallized fabrics, carbon-based composites, nickel-copper alloy coatings, silver-based conductive coatings, copper mesh materials, and zinc-based electromagnetic shielding materials. The EMI shield can incorporate multiple layers with different electromagnetic shielding properties, specifically tuned to the operating frequencies of the memory sub-system 302. These materials are carefully selected and configured to provide shielding effectiveness across various frequencies while maintaining compatibility with the thermal management system.

The EMI shield 210 includes strategically placed ventilation openings that allow proper airflow for thermal management without compromising EMI protection. These openings are positioned to enhance heat dissipation through the TCM 208 layer while maintaining effective electromagnetic containment. This comprehensive approach to EMI management, combining active monitoring and adjustment with physical shielding, ensures system reliability while maintaining optimal performance levels. The integration of multiple measurement techniques with adaptive control strategies provides robust protection against electromagnetic interference while preserving system functionality.

The cross-sectional view 202 demonstrates how the EMI shield 210 and TCM 208 work together as an integrated solution and part of the plurality of layers covering the components on the PCB 204, such as the memory sub-system 206 (e.g., SSD). The TCM 208 provides thermal management and initial EMI containment, while the EMI shield 210 adds targeted electromagnetic shielding. This dual-layer approach optimizes both thermal dissipation and EMI protection in a space-efficient design.

FIG. 3 illustrates an example computing system 301 that includes a memory sub-system 302 implemented on the PCB 204, in accordance with some examples. The memory sub-system 302 can include media, such as one or more volatile memory devices (e.g., memory device 312), one or more non-volatile memory devices (e.g., memory device 310), or a combination of such.

The memory sub-system 302 can be a storage device, a memory module, or a hybrid of a storage device and memory module. Examples of a storage device include a SSD, a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM). In general, a host system 309 can utilize the memory sub-system 302 that includes one or more components, such as memory devices that store data. The host system 309 can send access requests to the memory sub-system 302, such as to store data at the memory sub-system 302 and to read data from the memory sub-system 302 via the interface 105. The memory sub-system 302 can be implemented on a circuit board that includes an EMI shield 102.

The host system 309 can send access requests (e.g., write command, read command, erase command) to the memory sub-system, such as to read and/or store data on a memory device at the memory sub-system, read data from the memory device on the memory sub-system 302, or write/read constructs (e.g., such as submission and completion queues) with respect to a memory device on the memory sub-system. The data to be read or written, as specified by a host request, is hereinafter referred to as “host data” or “user data.”

A memory device (e.g., memory device 310) can be a non-volatile memory device. A non-volatile memory device is a package of one or more die. Each die can be comprised of one or more planes. For some types of non-volatile memory devices (e.g., AND-type devices), each plane is comprised of a set of physical blocks. For some memory devices, blocks are the smallest area that can be erased. Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are raw memory devices combined with a local embedded controller for memory management within the same memory device package. The memory device can be divided into one or more zones where each zone is associated with a different set of host data or user data or application.

Certain memory devices, such as NAND-type memory devices, include one or more blocks, (e.g., multiple blocks), with each of those blocks including multiple memory cells. For instance, a memory device can include multiple pages (stored across one or more WLs), with each page including a subset of memory cells of the memory device. A threshold voltage (VT) of a memory cell (of a block) can be the voltage at which the floating gate (e.g., NAND transistor), implementing the memory cell, turns on and conducts (e.g., to a bit line coupled to the memory cell). Generally, writing data to such memory devices involves programming (by way of a program operation) the memory devices at the page level of a block, and erasing data from such memory devices involves erasing the memory devices at the block level (e.g., page level erasure of data is not possible).

The computing system 301 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The host system 309 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 309 uses the memory sub-system 302, for example, to write data to the memory sub-system 302 and read data from the memory sub-system 302.

The host system 309 can include or be coupled to the memory sub-system 302 so that the host system 309 can read data from or write data to the memory sub-system 302. The host system 309 can be coupled to the memory sub-system 302 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 309 and the memory sub-system 302. The host system 309 can further utilize an NVM Express (NVMe) interface to access the memory devices 310, 312 when the memory sub-system 302 is coupled with the host system 309 by the PCIe or CXL interface. The physical host interface can provide an interface for passing control, address, data, and other signals between the memory sub-system 302 and the host system 309.

The memory devices 310, memory device 312 can include any combination of the different types of non-volatile memory devices and/or volatile memory devices. The volatile memory devices (e.g., memory device 312) can be, but are not limited to, random access memory (RAM), such as dynamic random access memory (DRAM) and synchronous dynamic random access memory (SDRAM). Some examples of non-volatile memory devices (e.g., memory device 310) include a NAND type flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 310, 312 can include one or more arrays of memory cells. One type of memory cell, for example, single level cells (SLCs), can store one bit per cell. Other types of memory cells, such as multi-level cells (MLCs), tri-level cells (TLCs), quad-level cells (QLCs), and penta-level cells (PLCs), can store multiple bits per cell. In some examples, each of the memory devices 310, 312 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 310, 312 can be grouped as pages that can refer to a logical unit of the memory device used to store data. With some types of memory (e.g., NAND), pages can be grouped to form blocks or BSs. As used herein, a block including SLCs can be referred to as a SLC block, a block including MLCs can be referred to as a MLC block, a block including TLCs can be referred to as a TLC block, and a block including QLCs can be referred to as a QLC block.

Although non-volatile memory components such as NAND type flash memory (e.g., 2D NAND, 3D NAND) and 3D cross-point array of non-volatile memory cells are described, the memory device 310 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 304 (or controller 304 for simplicity) can communicate with the memory devices 310, 312 to perform operations such as reading data, writing data, or erasing data (e.g., performing GC operations) at the memory devices 310, 312 and other such operations. The memory sub-system controller 304 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 304 can be a microcontroller, special purpose logic circuitry (e.g., a field programmable gate array (FPGA), an application specific integrated circuit (ASIC), and so forth), or other suitable processor. In some cases, the memory device 310 and memory device 312 operate at high frequencies that can interfere with other external components of the computing system 301, such as a 2.4 GHz WiFi device. The interface 105 and/or interface between the memory sub-system controller 304 and the memory device 312 can operate at such rates, such as 2400 MT/s ONFI which can emit electromagnetic emissions that interfere with other components of the computing system 301. The EMI shield 102 placed on the memory sub-system 302 or PCB 101 implementing the memory sub-system 302 can reduce or eliminate such electromagnetic emissions.

The memory sub-system controller 304 can include a processor (processing device 306 configured to execute instructions stored in local memory 308. In the illustrated example, the local memory 308 of the memory sub-system controller 304 includes an embedded memory configured to store instructions for performing various processes, operations, logic flows, and routines that control operation of the memory sub-system 302, including handling communications between the memory sub-system 302 and the host system 309.

In some examples, the local memory 308 can include memory registers storing memory pointers, fetched data, and so forth. The local memory 308 can also include ROM for storing micro-code. While the example memory sub-system 302 in FIG. 3 has been illustrated as including the memory sub-system controller 304, in another example, a memory sub-system 302 does not include a memory sub-system controller 304, and can instead rely upon external control (e.g., provided by an external host, or by a processor or controller separate from the memory sub-system).

In general, the memory sub-system controller 304 can receive commands or operations from the host system 309 and can convert the commands or operations into instructions or appropriate commands to achieve the desired access to the memory device 130 and/or the memory device 312. The memory sub-system controller 304 can be responsible for other operations such as wear leveling operations, GC operations, error detection and ECC operations, encryption operations, caching operations, and address translations between a logical address (e.g., LBA, namespace) and a physical memory address (e.g., physical block address in a physical address space of the memory device 310 or memory device 312) that are associated with the memory devices 310, 312. The memory sub-system controller 304 can further include host interface circuitry to communicate with the host system 309 via the physical host interface. The host interface circuitry can convert the commands received from the host system 309 into command instructions to access the memory device 310 and/or the memory device 312 as well as convert responses associated with the memory device 310 and/or the memory device 312 into information for the host system 309.

The memory sub-system 302 can also include additional circuitry or components that are not illustrated. In some examples, the memory sub-system 302 can include a cache or buffer (e.g., DRAM) and address circuitry (e.g., a row decoder and a column decoder) that can receive an address from the memory sub-system controller 304 and decode the address to access the memory devices 310, 312.

In some examples, the memory device 310 includes local media controllers 311 that operate in conjunction with memory sub-system controller 304 to execute operations on one or more memory cells of the memory device 310. An external controller (e.g., memory sub-system controller 304) can externally manage the memory device 310 (e.g., perform media management operations on the memory device 310). In some examples, a memory device 310 is a managed memory device, which is a raw memory device combined with a local controller (e.g., local media controller 135) for media management within the same memory device package. An example of a managed memory device is a managed NAND (mNAND) device. Any operation discussed as being performed by the memory sub-system controller 304 can be similarly performed by the local media controllers 311 and vice versa. The local media controllers 311 may, in some cases, also emit electromagnetic emissions that can interfere with external components of the computing system 301. The EMI shield 102 can reduce or prevent such emissions from the local media controllers 311.

The memory sub-system controller 304 can include an operations management unit 303 both of which are protected by the plurality of layers 313 (e.g., a TCM and/or an EMI shield (which itself can include multiple layers) and/or one or more additional insulating or non-conductive layers). In some cases, the operations management unit 303 can be a separate physical component from the components of the memory sub-system controller 304. In some cases, the operations management unit 303 and the components of the memory sub-system controller 304 are implemented by the same physical device or integrated circuit.

In some examples, the plurality of layers 313 can be implemented by a material (e.g., a potting material, such as epoxies (e.g., with 1.48 W/mK), urethanes (e.g., with 2.5 W/mK or 0.2 W/mK), silicone adhesives, a thermal epoxy with a 1 W/m-K thermal conductivity and/or a phase change material with a 0.7 W/m-K thermal conductivity) coupled to a ground layer of a PCB on which the memory sub-system 302 is implemented. In such cases, the plurality of layers 313 can be any combination of a first type of material (e.g., potting material) and/or a second type of material (e.g., a phase change material (PCM)) and an EMI shield. Heat can be transferred to the plurality of layers 313 by having thermal contact between the plurality of layers 313 and individual components on the PCB. Such heat can be dissipated to the external fluid or gas. In this way, the plurality of layers 313 acts as a heat sink, and temperature of the memory sub-system 302 can be reduced or maintained at a relatively low level to prevent the operations management unit 303 from reducing throughput of the memory sub-system 302 in response to detecting that the temperature of one or more components of the memory sub-system 302 transgresses a temperature threshold or reference temperature. This keeps the data rate operating at the optimal or maximum level which improves the overall efficiency and functioning of the device. In some examples, the plurality of layers 313 can collect heat dissipated by one or more components of the memory sub-system controller 304 and/or the memory sub-system 302, such as the memory device 310.

In some examples, the EMI shield (which can be included as part of the plurality of layers 313) can be implemented as an additional layer placed on an exposed surface to cover the TCM or non-conductive layer of the plurality of layers 313 to provide comprehensive electromagnetic shielding while maintaining effective thermal management. The EMI shield layer works in conjunction with the TCM layer, which can include materials such as thermal epoxy with specific thermal conductivity ratings or phase change materials, to address both electromagnetic emissions and heat dissipation. The operations management unit 303 can actively manage electromagnetic emissions through a monitoring and adjustment system. Specifically, the operations management unit 303 can be configured to measure electromagnetic emissions from the memory devices 310 and processing components using electromagnetic field sensors to detect field strength in proximity to the memory sub-system 302. When measured emissions exceed defined threshold values, the operations management unit 303 can dynamically adjust operating parameters of the affected components to maintain emissions within acceptable ranges.The EMI shield can fully cover the components of the memory sub-system 206 and/or partially cover the components. Namely, the EMI shield can fully cover components of the memory sub-system 206 associated with a threshold amount of EMI and partially cover other components or not cover at all other components that are associated with less than the threshold amount of EMI.

This adaptive EMI management approach allows the system to optimize performance while ensuring electromagnetic compatibility. The operations management unit 303 can continuously monitor emission levels and make real-time adjustments to parameters such as operating frequencies or data transfer rates based on the measured EMI levels. This helps maintain system reliability and performance while preventing electromagnetic interference with nearby components.

The EMI shield's placement on an exposed surface of the TCM creates a layered protection approach. The TCM provides thermal management and initial EMI containment, while the dedicated EMI shield layer provides additional targeted electromagnetic shielding. This configuration allows the system to effectively manage both thermal and electromagnetic challenges while maintaining optimal operating conditions for the memory sub-system. The EMI shield can be selectively placed on TCM-covered areas while being excluded from other portions of the PCB, allowing for strategic shielding of components that generate higher levels of electromagnetic emissions. This targeted approach helps optimize the shielding configuration while maintaining access to components that require less EMI protection.

In some implementations, the EMI shield can include strategically placed ventilation openings while maintaining effective electromagnetic shielding capabilities. These openings can be configured to allow proper airflow for thermal management purposes without compromising the shield's ability to contain electromagnetic emissions. The ventilation openings can be sized and positioned based on the specific shielding requirements and emission patterns of different components, allowing for optimized airflow in areas that require additional cooling while maintaining sufficient EMI protection. This approach enables the system to balance thermal management needs with EMI containment, as the shield can still effectively reduce electromagnetic emissions even with carefully designed openings. The ventilation configuration can be important for high-power components that may need both EMI shielding and enhanced cooling capabilities.

In some cases, an additional insulating layer can be included to cover the EMI shield as one of the layers of the plurality of layers 313. This additional insulating layer (an insulator protecting from electrical shorts in components that touch the EMI shield) can be placed on an exposed surface to cover the EMI shield layer (e.g., a top surface of the EMI shield).

In some examples, a PCB is provided having an exposed surface on which physical components are implemented including the set of memory device 310 and the processing device (e.g., memory sub-system controller 304). In some examples, the PCB includes a plurality of layers each accessible through one or more vias, the plurality of layers including a ground layer. Exposed surfaces of the physical components including the set of memory device 310 and the memory sub-system controller 304 are both surrounded (partially and/or entirely) and covered by one of the layers of the plurality of layers 313 that include a TCM and/or EMI shield. Other active or passive components (e.g., DC-DC converters, interfaces, resistors, capacitors, inductors, and/or transistors) that are smaller in height than physical components implementing the set of memory components and the memory sub-system controller 304 can be fully encapsulated by the TCM and covered by the EMI shield. In some cases, the TCM is made up of a first material type that physically and thermally surrounds the set of memory device 310 and is made up of a second material type that physically and thermally surrounds the memory sub-system controller 304. Then, the EMI shield making up another one of the layers of the plurality of layers 313 is placed or deposited on an exposed surface of any area that includes the TCM.

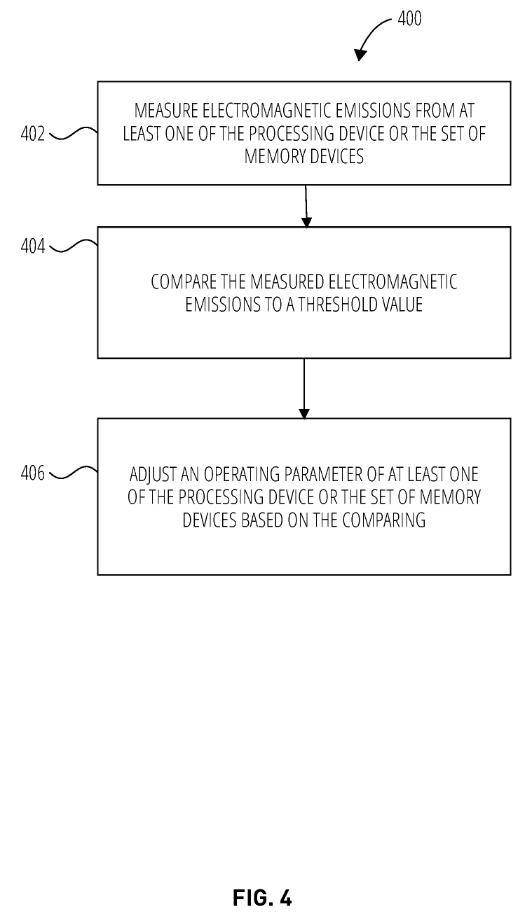

FIG. 4 illustrates a flow diagram 400 showing operations performed by the operations management unit 303. The process can be implemented through various forms of processing logic, including hardware components (such as processing devices, dedicated logic circuits, programmable logic, microcode, or integrated circuits), software instructions executed on a processing device, or combinations thereof. The memory sub-system controller 304 or its subcomponents can perform these operations, with the operations management unit 303 handling key aspects of the process.

The flow diagram 400 begins at operation 402, where electromagnetic emissions are measured by the operations management unit 303 from at least one of the processing device or the set of memory devices 310. This measurement can be performed using electromagnetic field sensors to detect field strength in proximity to the memory sub-system components.

At operation 404, the measured electromagnetic emissions are compared by the operations management unit 303 to a threshold value to determine if they exceed acceptable levels. At operation 406, based on the comparison, an operating parameter of at least one of the processing device or the set of memory devices is adjusted by the operations management unit 303. This adjustment can include modifying data transfer rates, operating frequencies, or other parameters to maintain electromagnetic emissions within acceptable ranges.

The operations management unit 303 can implement various adjustment strategies through this process, including reducing data transfer rates between the host and memory components, modifying operating frequencies of specific components, or adjusting power delivery patterns. This flow enables continuous monitoring and dynamic adjustment of system parameters to manage electromagnetic emissions effectively while preserving optimal performance levels of the memory sub-system.

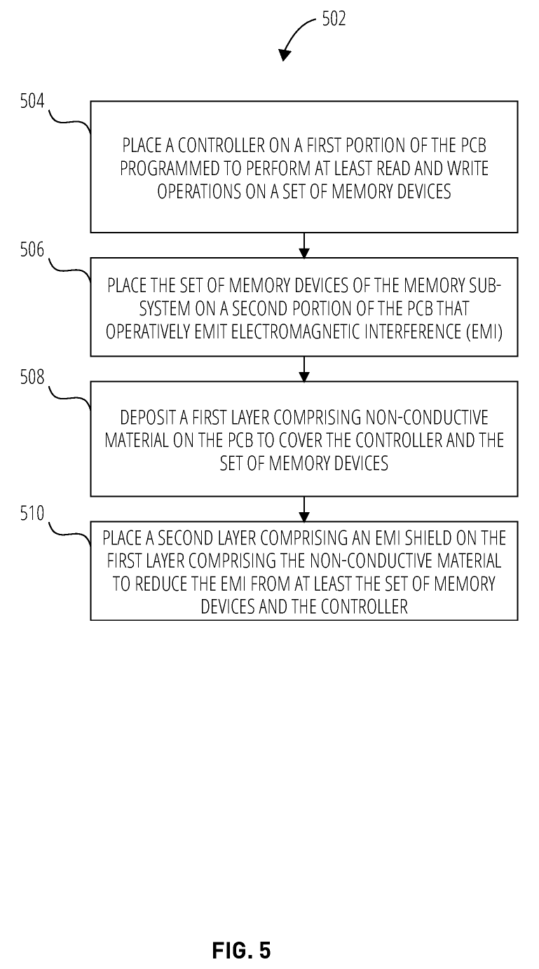

FIG. 5 illustrates a flow diagram showing a routine 502 of operations for manufacturing a memory sub-system 302 with EMI shielding capabilities, in accordance with some examples. The routine 502 can be implemented through various manufacturing steps and assembly procedures to create an integrated EMI shielding solution. The routine 502 of FIG. 5 can be implemented through various forms of processing logic, including hardware components (such as processing devices, dedicated logic circuits, programmable logic, microcode, or integrated circuits), software instructions executed on a processing device, or combinations thereof.

The flow diagram begins at operation 504, where a controller is placed on a first portion of the PCB programmed to perform at least read and write operations on a set of memory devices. This involves mounting a first physical component that includes the memory sub-system controller 304 at a designated location while maintaining specified height requirements relative to the PCB surface. Then, at operation 506, the set of memory devices of the memory sub-system is placed on a second portion of the PCB that operatively emit EMI. The set of physical components including the memory devices are positioned to maintain proper spacing and height requirements while enabling effective thermal management and EMI shielding.

At operation 508, a first layer including a non-conductive material is deposited on the PCB to cover at least the memory sub-system controller 304 and the memory device 310. The non-conductive material can include a TCM which includes materials like thermal epoxy or phase change materials to provide effective heat dissipation. At operation 510, a second layer including an EMI shield is placed on an exposed surface of the TCM, such as the first layer. This EMI shield is configured to reduce electromagnetic emissions from the memory sub-system controller 304 and memory devices 310 while working in conjunction with the TCM layer for thermal management.

This manufacturing flow enables the creation of a memory sub-system with integrated thermal and EMI management capabilities. The layered approach ensures both proper heat dissipation through the TCM and effective electromagnetic shielding through the EMI shield while maintaining compatibility with standard form factors and height restrictions.

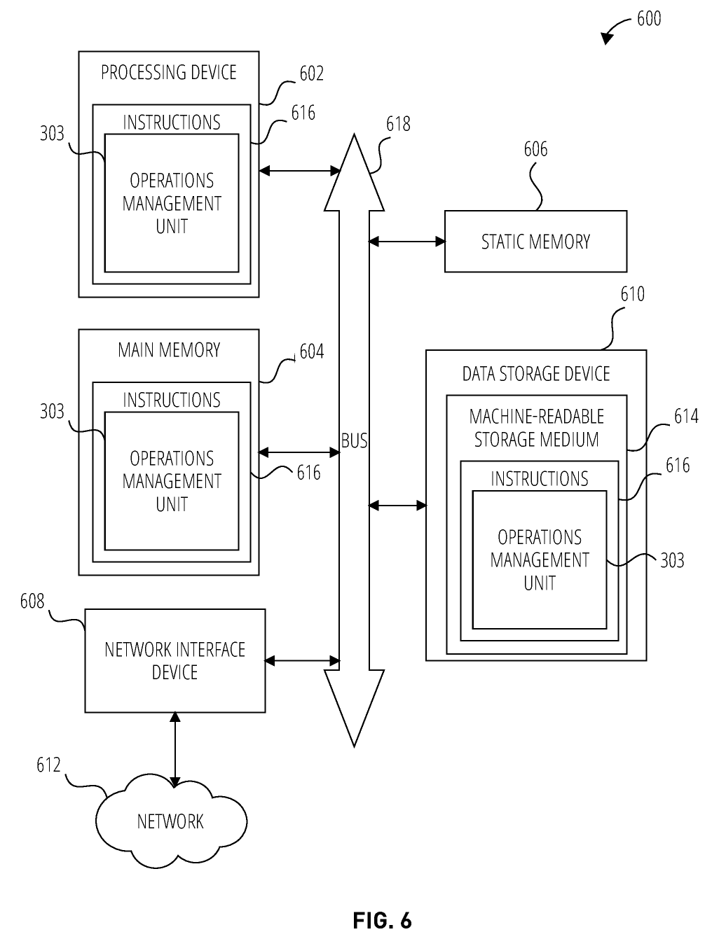

FIG. 6 illustrates an example machine in the form of a computer system 600 within which a set of instructions can be executed for causing the machine to perform any one or more of the methodologies discussed herein. In some examples, the computer system 600 can correspond to a host system (e.g., the host system 309 of FIG. 3) that includes, is coupled to, or utilizes a memory sub-system (e.g., the memory sub-system 302 of FIG. 3) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., ROM, flash memory, DRAM such as SDRAM or Rambus DRAM (RDRAM), etc.), a static memory 606 (e.g., flash memory, static random access memory (SRAM), etc.), and a data storage device 610, which communicate with each other via a bus 618.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application-specific integrated circuit (ASIC), a field programmable gate array (FPGA), a digital signal processor (DSP), a network processor, or the like. The processing device 602 is configured to execute instructions 616 for performing the operations and steps discussed herein. The computer system 600 can further include a network interface device 608 to communicate over a network 612.

The data storage device 610 can include a machine-readable storage medium 614 (also known as a computer-readable medium) on which is stored one or more sets of instructions 616 or software embodying any one or more of the methodologies or functions described herein. The instructions 616 can also reside, completely or at least partially, within the main memory 604 and/or within the processing device 602 during execution thereof by the computer system 600, the main memory 604 and the processing device 602 also constituting machine-readable storage media. The machine-readable storage medium 614, data storage device 610, and/or main memory 604 can correspond to the memory sub-system 302 of FIG. 3.

In one example, the instructions 616 include instructions to implement functionality corresponding to providing block failure protection for a zone memory sub-system as described herein (e.g., the operations management unit 303 of FIG. 3). While the machine-readable storage medium 614 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1. A memory sub-system comprising: a set of memory devices of the memory sub-system that operatively emit electromagnetic interference (EMI); a controller including at least one processor, the at least one processor coupled to the set of memory devices and programmed to perform at least read and write operations on the set of memory devices; and a plurality of layers comprising a non-conductive material and an EMI shield, the plurality of layers covering at least the set of memory devices and the controller to reduce the EMI from at least the set of memory devices and the controller, the non-conductive material being disposed between the EMI shield and at least the set of memory devices and the controller covered by the plurality of layers.

Example 2. The memory sub-system of Example 1, wherein the non-conductive material comprises a thermally conductive material (TCM), and wherein the EMI shield comprises a metallic material.

Example 3. The memory sub-system of Example 2, wherein the EMI shield comprises at least one of: a metal foil layer; a conductive polymer material; a metalized fabric; a carbon-based composite material; a nickel-copper alloy coating; a silver-based conductive coating; a copper mesh material; or a zinc-based electromagnetic shielding material.

Example 4. The memory sub-system of any one of Examples 2-3, wherein the EMI shield is configured to provide electromagnetic shielding in a frequency range corresponding to operating frequencies of the memory sub-system.

Example 5. The memory sub-system of any one of Examples 2-4, wherein the TCM comprises a potting material comprising a thermal epoxy or phase change material (PCM).

Example 6. The memory sub-system of any one of Examples 2-5, the TCM surrounding at least the set of memory devices and the controller, the TCM configured to dissipate heat from the controller and the set of memory devices.

Example 7. The memory sub-system of any one of Examples 2-6, wherein the memory sub-system comprises a solid-state drive (SSD).

Example 8. The memory sub-system of any one of Examples 1-7, wherein the non-conductive material comprises a gel or plastic material.

Example 9. The memory sub-system of any one of Examples 1-8, wherein the memory sub-system is implemented on a printed circuit board (PCB), wherein a total height of the PCB including heights of the set of memory devices, the controller, and the plurality of layers is less than a specified threshold.

Example 10. The memory sub-system of Example 9, wherein the PCB comprises an M.2 interface through which the controller communicates with a host, the specified threshold comprising 2.3 millimeters, the PCB having a width of 22 millimeters, and a length of 30 millimeters or a width of 42 millimeters, and a length of 80 millimeters.

Example 11. The memory sub-system of Example 10, wherein one or more passive or active components are implemented on the PCB, wherein at least a portion of the plurality of layers covers the one or more passive or active components.

Example 12. The memory sub-system of Example 11, wherein the one or more passive or active components comprise at least one of interface connectors or DC-DC converters that emit EMI.

Example 13. The memory sub-system of any one of Examples 9-12, wherein the EMI shield is excluded from portions of the PCB that are uncovered by the non-conductive material.

Example 14. The memory sub-system of any one of Examples 1-14, wherein the controller is programmed to perform operations comprising: measuring electromagnetic emissions from at least the controller or the set of memory devices; comparing the measured electromagnetic emissions to a threshold value; and adjusting an operating parameter of at least one of the controller or the set of memory devices based on the comparing.

Example 15. The memory sub-system of Example 14, wherein measuring electromagnetic emissions comprises using an electromagnetic field sensor to detect electromagnetic field strength in proximity to the memory sub-system.

Example 16. The memory sub-system of any one of Examples 1-15, wherein the EMI shield includes ventilation openings configured to allow airflow while maintaining electromagnetic shielding.

Example 17. The memory sub-system of any one of Examples 1-16, wherein the non-conductive material is placed on an exposed surface of at least the set of memory devices and the controller, and wherein the EMI shield is placed on an exposed surface of the non-conductive material.

Example 18. A method comprising: providing a set of memory devices of a memory sub-system that operatively emit electromagnetic interference (EMI); providing a controller including at least one processor, the at least one processor coupled to the set of memory devices and programmed to perform at least read and write operations on the set of memory devices; and placing a plurality of layers comprising a non-conductive material and an EMI shield on at least the set of memory devices and the controller, the plurality of layers covering at least the set of memory devices and the controller to reduce the EMI from at least the set of memory devices and the controller, the non-conductive material being disposed between the EMI shield and at least the set of memory devices and the controller covered by the plurality of layers.

Example 19. The method of Example 18, wherein the non-conductive material comprises a thermally conductive material (TCM), and wherein the EMI shield comprises a metallic material.

Example 20. A method of manufacturing a printed circuit board (PCB) comprising a memory sub-system, the method comprising: placing a controller on a first portion of the PCB programmed to perform at least read and write operations on a set of memory devices; placing the set of memory devices of the memory sub-system on a second portion of the PCB that operatively emit electromagnetic interference (EMI); depositing a first layer comprising non-conductive material on the PCB to cover the controller and the set of memory devices; and placing a second layer comprising an EMI shield on the first layer comprising the non-conductive material to reduce the EMI from at least the set of memory devices and the controller.

Methods and computer-readable storage medium with instructions for performing any one of the above examples.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

“Exposed surface” herein generally refers to an outward-facing or uncovered area of a physical component or material layer that is accessible from the exterior of the physical component. Exposed surface can alternatively or optionally be referred to as a top surface of a physical component, outwardly facing surface of a physical component, a surface along a plane that is parallel to a plane of a surface of a PCB, an outer surface area, an external facing portion, an accessible exterior surface, and/or an uppermost component layer. Exposed surface become unexposed when another physical element/component is placed on top of the exposed surface of the physical component.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

1. A memory sub-system comprising:
a set of memory devices of the memory sub-system that operatively emit electromagnetic interference (EMI);
a controller including at least one processor, the at least one processor coupled to the set of memory devices and programmed to perform at least read and write operations on the set of memory devices; and
a plurality of layers comprising a non-conductive material and an EMI shield, the plurality of layers covering at least the set of memory devices and the controller to reduce the EMI from at least the set of memory devices and the controller, the non-conductive material being disposed between the EMI shield and at least the set of memory devices and the controller covered by the plurality of layers.

2. The memory sub-system of claim 1, wherein the non-conductive material comprises a thermally conductive material (TCM), and wherein the EMI shield comprises a metallic material.

3. The memory sub-system of claim 2, wherein the EMI shield comprises at least one of: a metal foil layer; a conductive polymer material; a metalized fabric; a carbon-based composite material; a nickel-copper alloy coating; a silver-based conductive coating; a copper mesh material; or a zinc-based electromagnetic shielding material.

4. The memory sub-system of claim 2, wherein the EMI shield is configured to provide electromagnetic shielding in a frequency range corresponding to operating frequencies of the memory sub-system.

5. The memory sub-system of claim 2, wherein the TCM comprises a potting material comprising a thermal epoxy or phase change material (PCM).

6. The memory sub-system of claim 2, the TCM surrounding at least the set of memory devices and the controller, the TCM configured to dissipate heat from the controller and the set of memory devices.

7. The memory sub-system of claim 2, wherein the memory sub-system comprises a solid-state drive (SSD).

8. The memory sub-system of claim 1, wherein the non-conductive material comprises a gel or plastic material.

9. The memory sub-system of claim 1, wherein the memory sub-system is implemented on a printed circuit board (PCB), wherein a total height of the PCB including heights of the set of memory devices, the controller, and the plurality of layers is less than a specified threshold.

10. The memory sub-system of claim 9, wherein the PCB comprises an M.2 interface through which the controller communicates with a host, the specified threshold comprising 2.3 millimeters, the PCB having a width of 22 millimeters, and a length of 30 millimeters or a width of 42 millimeters, and a length of 80 millimeters.

11. The memory sub-system of claim 10, wherein one or more passive or active components are implemented on the PCB, wherein at least a portion of the plurality of layers covers the one or more passive or active components.

12. The memory sub-system of claim 11, wherein the one or more passive or active components comprise at least one of interface connectors or DC-DC converters that emit EMI.

13. The memory sub-system of claim 9, wherein the EMI shield is excluded from portions of the PCB that are uncovered by the non-conductive material.

14. The memory sub-system of claim 1, wherein the controller is programmed to perform operations comprising:
measuring electromagnetic emissions from at least the controller or the set of memory devices;
comparing the measured electromagnetic emissions to a threshold value; and
adjusting an operating parameter of at least one of the controller or the set of memory devices based on the comparing.

15. The memory sub-system of claim 14, wherein measuring electromagnetic emissions comprises using an electromagnetic field sensor to detect electromagnetic field strength in proximity to the memory sub-system.

16. The memory sub-system of claim 1, wherein the EMI shield includes ventilation openings configured to allow airflow while maintaining electromagnetic shielding.

17. The memory sub-system of claim 1, wherein the non-conductive material is placed on an exposed surface of at least the set of memory devices and the controller, and wherein the EMI shield is placed on an exposed surface of the non-conductive material.

18. A method comprising:
providing a set of memory devices of a memory sub-system that operatively emit electromagnetic interference (EMI);
providing a controller including at least one processor, the at least one processor coupled to the set of memory devices and programmed to perform at least read and write operations on the set of memory devices; and
placing a plurality of layers comprising a non-conductive material and an EMI shield on at least the set of memory devices and the controller, the plurality of layers covering at least the set of memory devices and the controller to reduce the EMI from at least the set of memory devices and the controller, the non-conductive material being disposed between the EMI shield and at least the set of memory devices and the controller covered by the plurality of layers.

19. The method of claim 18, wherein the non-conductive material comprises a thermally conductive material (TCM), and wherein the EMI shield comprises a metallic material.

20. A method of manufacturing a printed circuit board (PCB) comprising a memory sub-system, the method comprising:
placing a controller on a first portion of the PCB programmed to perform at least read and write operations on a set of memory devices;
placing the set of memory devices of the memory sub-system on a second portion of the PCB that operatively emit electromagnetic interference (EMI);
depositing a first layer comprising non-conductive material on the PCB to cover the controller and the set of memory devices; and
placing a second layer comprising an EMI shield on the first layer comprising the non-conductive material to reduce the EMI from at least the set of memory devices and the controller.
